(19) United States
(12) Patent Application Publication
(10) Pub. No.: US 2023/0178965 A1
(43) Pub. Date: Jun. 8, 2023

(54) SEMICONDUCTOR STACK AND LIGHT-EMITTING DEVICE

(71) Applicant: SUMITOMO ELECTRIC INDUSTRIES, LTD., Osaka (JP)

(72) Inventors: Takuma FUYUKI, Osaka (JP); Susumu YOSHIMOTO, Osaka (JP)

(21) Appl. No.: 17/974,972

(22) Filed: Oct. 27, 2022

(30) Foreign Application Priority Data
Dec. 2, 2021 (JP) 2021-196414

(51) Int. Cl. H01S 5/343; H01S 5/34

(52) U.S. Cl. CPC H01S 5/34313; H01S 5/3408

(57) ABSTRACT

A semiconductor stack includes a first-conductivity-type layer, a quantum well structure, and a second-conductivity-type layer. The first-conductivity-type layer, the quantum well structure, and the second-conductivity-type layer are stacked in this order. The quantum well structure includes a first semiconductor layer, a second semiconductor layer, and a third semiconductor layer. In the first semiconductor layer and the third semiconductor layer, compositions of the first semiconductor layer and the third semiconductor layer are changed such that a bandgap decreases toward the second semiconductor layer. Transition of an electron is possible between a conduction band of each of the first semiconductor layer and the third semiconductor layer and a valence band of the second semiconductor layer.

### CROSS REFERENCE TO RELATED APPLICATIONS

This application claims priority based on Japanese Patent Application No. 2021-196414 filed on Dec. 2, 2021, and the entire contents of the Japanese patent application are incorporated herein by reference.

### TECHNICAL FIELD

The present disclosure relates to a semiconductor stack and a light-emitting device.

### BACKGROUND ART

A semiconductor stack made of a III-V compound semiconductor can be used to manufacture a light-emitting device that emits light in the infrared region. Specifically, for example, a first-conductivity-type layer made of a III-V compound semiconductor, a quantum well structure, and a second-conductivity-type layer are sequentially stacked on a substrate made of a III-V compound semiconductor to form a semiconductor stack, and an appropriate electrode is further formed. Thus, a light-emitting device that emits light corresponding to the bandgap energy of the quantum well structure can be obtained.

Regarding such a quantum well structure capable of emitting and absorbing light in the infrared region, various configurations have been proposed (see, for example, PTL1 and Non-PTL1 to 3).
PTL 1: Japanese Unexamined Patent Application Publication No. 2012-222154
Non-PTL1: M. Peter, et al., “Realization and modeling of a pseudomorphic (GaAs₁₋ₓSbₓ—In_{y}Ga_{1-y}As)/GaAs bilayer-quantum well”, Appl. Phys. Lett. 67, 2639 (1995)
Non-PTL2: J. F. Klem, et al., “GaAsSb/InGaAs type-II quantum wells for long-wavelength lasers on GaAs substrates”, Journal of Vacuum Science & Technology B: Microelectronics and Nanometer Structures Processing, Measurement, and Phenomena 18, 1605 (2000)
Non-PTL3: C. Berger, et al., “Novel type-II material system for laser applications in the near-infrared regime”, AIP Advances 5, 047105 (2015)

### SUMMARY OF INVENTION

A semiconductor stack according to the present disclosure includes a first-conductivity-type layer formed of a III-V compound semiconductor, a quantum well structure formed of III-V compound semiconductors, and a second-conductivity-type layer formed of a III-V compound semiconductor and having a conductivity type different from a conductivity type of the first-conductivity-type layer. The first-conductivity-type layer, the quantum well structure, and the second-conductivity-type layer are stacked in this order. The quantum well structure includes a first semiconductor layer, a second semiconductor layer disposed on and in contact with the first semiconductor layer, and a third semiconductor layer disposed on and in contact with the second semiconductor layer. In the first semiconductor layer and the third semiconductor layer, compositions of the first semiconductor layer and the third semiconductor layer are changed such that a bandgap decreases toward the second semiconductor layer. Transition of an electron is possible between a conduction band of each of the first semiconductor layer and the third semiconductor layer and a valence band of the second semiconductor layer.

### BRIEF DESCRIPTION OF DRAWINGS

FIG. 1 is a schematic cross-sectional view showing a structure of a semiconductor stack according to a first embodiment.

FIG. 2 is a schematic cross-sectional view showing details of a quantum well structure.

FIG. 3 is a schematic cross-sectional view showing the structure of a light-emitting device according to a first embodiment.

FIG. 4 is a flow chart showing an outline of a method for manufacturing a semiconductor stack and a light-emitting device according to a first embodiment.

FIG. 5 is a flow chart showing an outline of a method of manufacturing a quantum well structure.

FIG. 6 is a schematic cross-sectional view showing a quantum well structure according to a second embodiment.

FIG. 7 is a schematic view showing band structures in quantum well structures of Examples and Comparative Examples.

FIG. 8 is a view showing the calculated wavelength of light emitted by the quantum well structures of Examples and Comparative Examples.

### DESCRIPTION OF EMBODIMENTS

In the light-emitting device including the semiconductor stack, the wavelength of emitted light may be adjusted by adjusting the composition of the semiconductor constituting the quantum well structure. However, when the composition of the semiconductor constituting the quantum well structure is adjusted so that the wavelength of the emitted light becomes longer, the strain in the quantum well structure tends to increase due to the difference in lattice constant of each layer in the semiconductor stack. As a result, there is a concern that the characteristics and durability of the light-emitting device are degraded due to the strain.

It is therefore an object of the present invention to provide a semiconductor stack and a light-emitting device capable of lengthening the wavelength of emitted light while suppressing an increase in strain in a quantum well structure.

### DESCRIPTION OF EMBODIMENTS OF PRESENT DISCLOSURE

First, embodiments of the present disclosure will be listed and described. A semiconductor stack of the present disclosure includes a first-conductivity-type layer formed of a III-V compound semiconductor, a quantum well structure formed of III-V compound semiconductors, and a second-conductivity-type layer formed of a III-V compound semiconductor and having a conductivity type different from a conductivity type of the first-conductivity-type layer. The first-conductivity-type layer, the quantum well structure, and the second-conductivity-type layer are stacked in this order. The quantum well structure includes a first semiconductor layer, a second semiconductor layer disposed on and in contact with the first semiconductor layer, and a third semiconductor layer disposed on and in contact with the second semiconductor layer. In the first semiconductor layer and the third semiconductor layer, compositions of the first semiconductor layer and the third semiconductor layer are changed such that a bandgap decreases toward the second semiconductor layer. Transition of an electron is possible between a conduction band of each of the first semiconductor layer and the third semiconductor layer and a valence band of the second semiconductor layer.

In the quantum well structure of the semiconductor stack of the present disclosure, the compositions of the first semiconductor layer and the third semiconductor layer are changed such that the bandgap decreases toward the second semiconductor layer. The strain in the quantum well structure is a value based on the average composition of each of the first semiconductor layer and the third semiconductor layer regardless of whether the compositions of the first semiconductor layer and the third semiconductor layer are constant or changed. On the other hand, if the average compositions of the first semiconductor layer and the third semiconductor layer are the same, the wavelength of light generated by the transition of electrons between the conduction band of each of the first semiconductor layer and the third semiconductor layer and the valence band of the second semiconductor layer becomes longer when the compositions of the first semiconductor layer and the third semiconductor layer change such that the bandgap decreases toward the second semiconductor layer than when the compositions are constant. Therefore, when the value of the strain in the quantum well structure is the same, the wavelength of the emitted light can be made longer by changing the composition so that the bandgap decreases toward the second semiconductor layer as compared with the case where the compositions of the first semiconductor layer and the third semiconductor layer are constant. That is, by changing the compositions of the first semiconductor layer and the third semiconductor layer so that the bandgap decreases toward the second semiconductor layer, it is possible to lengthen the wavelength of light emitted from the quantum well structure while suppressing an increase in strain in the quantum well structure. As described above, according to the semiconductor stack of the present disclosure, it is possible to lengthen the wavelength of emitted light while suppressing an increase in strain in the quantum well structure.

In the semiconductor stack, the first semiconductor layer and the third semiconductor layer may be formed of the same III-V compound semiconductor. With such a structure, the wavelength of light generated in the quantum well structure can be easily adjusted.

In the semiconductor stack, the first semiconductor layer and the third semiconductor layer may have the same thickness. Such a structure facilitates the design of a quantum well structure. Further, the first semiconductor layer and the third semiconductor layer may have the same composition at the same distance from the second semiconductor layer. Such a structure makes it easier to design a quantum well structure.

The semiconductor stack may further include a substrate formed of GaAs (gallium arsenide) and stacked opposite to the quantum well structure with the first-conductivity-type layer between them. The III-V compound semiconductors constituting the first semiconductor layer and the third semiconductor layer may be each InₓGa₁₋ₓAs_{y}N_{1-y} (indium gallium arsenide nitride). The III-V compound semiconductor constituting the second semiconductor layer may be GaSbₜAs₁₋ₜ (gallium antimonide arsenide) or GaBiᵤAs₁₋ᵤ, (gallium bismuthide arsenide). Here, 0<x<0.5, 0.9<y<1.0, 0<t<0.5, and 0<u<0.5 are satisfied.

In the semiconductor stack of the present disclosure, GaAs is suitable as a semiconductor (III-V compound semiconductor) constituting a substrate on the main surface of which the first-conductivity-type layer, the quantum well structure and the second-conductivity-type layer are grown. InₓGa₁₋ₓAs_{y}N_{1-y} (where 0<x<0.5, 0.9<y<1.0) is suitable as a III-V compound semiconductor constituting the first semiconductor layer and the third semiconductor layer. GaSbₜAs₁₋ₜ (where 0<t<0.5) and GaBiᵤAs₁₋ᵤ (where 0<u<0.5) are suitable as III-V compound semiconductors constituting the second semiconductor layer combined with the first semiconductor layer and the third semiconductor layer composed of InₓGa₁₋ₓAs_{y}N_{1-y}.

In the semiconductor stack, the compositions of the first semiconductor layer and the third semiconductor layer may be changed at a constant rate toward the second semiconductor layer. With such a structure, the quantum well structure included in the semiconductor stack of the present disclosure can be easily manufactured.

In the semiconductor stack, the compositions of the first semiconductor layer and the third semiconductor layer may be changed in stages toward the second semiconductor layer. Also with such a structure, the quantum well structure included in the semiconductor stack of the present disclosure can be easily manufactured.

In the semiconductor stack, the first semiconductor layer, the second semiconductor layer, and the third semiconductor layer each may have a thickness of 1 nm to 8 nm. In a region where the first semiconductor layer and the second semiconductor layer are in contact with each other and a region where the third semiconductor layer and the second semiconductor layer are in contact with each other, atoms constituting the respective semiconductor layers are mutually diffused to form a region (mutual diffusion region) having low light emission characteristics deviated from a designed composition. When the thicknesses of the first semiconductor layer, the second semiconductor layer, and the third semiconductor layer are reduced, the ratio of the mutual diffusion region to the entire quantum well structure increases, and the light emission characteristics deteriorate. From the viewpoint of suppressing such deterioration of the light emission characteristics, the thicknesses of the first semiconductor layer, the second semiconductor layer, and the third semiconductor layer may be 1 nm or more, or may be 2 nm or more, respectively. On the other hand, when the thicknesses of the first semiconductor layer, the second semiconductor layer, and the third semiconductor layer are increased, the transition probability of electrons decreases, and the light emission characteristics deteriorate. From the viewpoint of suppressing such deterioration of the light emission characteristics, the thicknesses of the first semiconductor layer, the second semiconductor layer, and the third semiconductor layer may be 8 nm or less, or may be 6 nm or less, respectively.

A light-emitting device according to the present disclosure includes the semiconductor stack and an electrode disposed in contact with the semiconductor stack. The light-emitting device of the present disclosure includes the semiconductor stack of the present disclosure. Therefore, according to the light-emitting device of the present disclosure, it is possible to lengthen the wavelength of emitted light while suppressing an increase in strain in the quantum well structure.

### DETAILS OF EMBODIMENTS OF PRESENT DISCLOSURE

Next, embodiments of a semiconductor stack according to the present disclosure will be described below with reference to the drawings. In the following drawings, the same or corresponding portions are denoted by the same reference numerals, and description thereof will not be repeated.

### First Embodiment

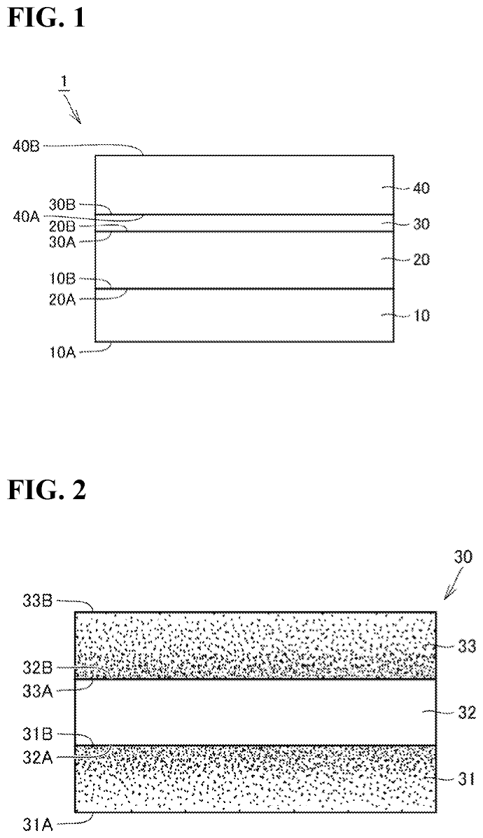

Referring to FIG. 1, a semiconductor stack 1 according to the first embodiment includes a substrate 10, an n-type cladding layer 20 as a first-conductivity-type layer, a quantum well structure 30, and a p-type cladding layer 40 as a second-conductivity-type layer.

Substrate 10 is made of a III-V compound semiconductor. Substrate 10 has a radius of, for example, 50 mm or more. The diameter of substrate 10 can be, for example, 3 inches. As the III-V compound semiconductor constituting substrate 10, for example, GaAs, GaP (gallium phosphide), GaSb (gallium antimonide), InP (indium phosphide), InAs (indium arsenide), InSb (indium antimonide), AlSb (aluminum antimonide), or AlAs (aluminum antimonide) can be adopted. Substrate 10 includes a first main surface 10A and a second main surface 10B.

Specifically, for example, GaAs whose conductivity type is n-type (n-GaAs) is employed as the compound semiconductor constituting substrate 10. As the n-type impurity contained in substrate 10, for example, S (sulfur) or the like can be adopted. For the purpose of improving production efficiency and yield of a semiconductor device (light-emitting device) using semiconductor stack 1, substrate 10 can have a diameter of 80 mm or more (for example, 4 inches), further 100 mm or more (for example, 5 inches), and further 130 mm or more (for example, 6 inches).

N-type cladding layer 20 is disposed on and in contact with second main surface 10B of substrate 10. N-type cladding layer 20 includes a first main surface 20A and a second main surface 20B. At first main surface 20A, n-type cladding layer 20 is in contact with substrate 10. N-type cladding layer 20 is formed of a III-V compound semiconductor. As the III-V compound semiconductor constituting n-type cladding layer 20, for example, AlₓGa₁₋ₓAs (aluminum gallium arsenide) (0.10<x<0.90), InₓGa₁₋ₓP (indium gallium phosphide) (0.40<x<0.60), or the like can be adopted. In the present embodiment, for example, n-AlₓGa₁₋ₓAs (x=0.45) having an n-type conductivity type is employed as the compound semiconductors constituting n-type cladding layer 20. For example, Si (silicon) can be employed as an n-type impurity contained in n-type cladding layer 20. The thicknesses of N-type cladding layer 20 is, for example, from 300 nm to 3000 nm.

Quantum well structure 30 is disposed opposite to substrate 10 with n-type cladding layer 20 between them. Quantum well structure 30 is disposed on second main surface 20B of n-type cladding layer 20. Quantum well structure 30 includes a first main surface 30A and a second main surface 30B. At first main surface 30A, quantum well structure 30 is in contact with n-type cladding layer 20. Quantum well structure 30 is made of a III-V compound semiconductor.

FIG. 2 is a schematic cross-sectional view showing details of quantum well structure 30. Referring to FIG. 2, quantum well structure 30 of the present embodiment includes a first semiconductor layer 31, a second semiconductor layer 32, and a third semiconductor layer 33. First semiconductor layer 31, second semiconductor layer 32, and third semiconductor layer 33 respectively include first main surfaces 31A, 32A, and 33A which are main surfaces closer to substrate 10, and second main surfaces 31B, 32B, and 33B which are main surfaces farther from substrate 10. First semiconductor layer 31 is in contact with second main surface 20B of n-type cladding layer 20 at first main surface 31A. First main surface 31A is first main surface 30A of quantum well structure 30. First main surface 32A of second semiconductor layer 32 is in contact with second main surface 31B of first semiconductor layer 31. First main surface 33A of third semiconductor layer 33 is in contact with second main surface 32B of second semiconductor layer 32. Referring to FIGS. 1 and 2, second main surface 33B of third semiconductor layer 33 is in contact with a first main surface 40A of p-type cladding layer 40. Second main surface 33B of third semiconductor layer 33 is second main surface 30B of quantum well structure 30. First semiconductor layer 31, second semiconductor layer 32, and third semiconductor layer 33 are stacked in this order on second main surface 20B of n-type cladding layer 20.

The III-V compound semiconductors constituting first semiconductor layer 31, second semiconductor layer 32, and third semiconductor layer 33 can be appropriately selected in consideration of a desired emission wavelength. In the present embodiment, the III-V compound semiconductor constituting first semiconductor layer 31 and third semiconductor layer 33 is InₓGa₁₋ₓAs_{y}N_{1-y}. Here, 0<x<0.5 and 0.9<y<1.0 are satisfied. In the present embodiment, first semiconductor layer 31 and third semiconductor layer 33 are made of the same III-V compound semiconductor. In the present embodiment, the III-V compound semiconductor constituting second semiconductor layer 32 is GaSbₜAs₁₋ₜ or GaBiᵤAs₁₋ᵤ. Here, 0<t<0.5 and 0<u<0.5 are satisfied. First semiconductor layer 31 and third semiconductor layer 33 have the same thickness. The thicknesses of first semiconductor layer 31, second semiconductor layer 32, and third semiconductor layer 33 are, for example, from 2 nm to 6 nm, respectively. The thicknesses of first semiconductor layer 31, second semiconductor layer 32, and third semiconductor layer 33 may be the same. The thicknesses of first semiconductor layer 31, second semiconductor layer 32, and third semiconductor layer 33 are, for example, 4 nm, respectively.

In first semiconductor layer 31 and third semiconductor layer 33, compositions of first semiconductor layer 31 and third semiconductor layer 33 are changed such that the bandgap decreases toward second semiconductor layer 32. In FIG. 2, dots in first semiconductor layer 31 and third semiconductor layer 33 schematically indicate the concentration of In (indium). In first semiconductor layer 31 and third semiconductor layer 33, the concentration of In increases toward second semiconductor layer 32 (the value of x increases toward second semiconductor layer 32). In first semiconductor layer 31 and third semiconductor layer 33, the concentration of In is symmetrical with respect to second semiconductor layer 32. In the present embodiment, the compositions of first semiconductor layer 31 and third semiconductor layer 33 change at a constant rate toward second semiconductor layer 32. More specifically, the concentration (atomic ratio; at %) of In in first semiconductor layer 31 and third semiconductor layer 33 is a linear function of the distance from second semiconductor layer 32. In addition, electron transition (type II transition) may occur between the conduction band of each of first semiconductor layer 31 and third semiconductor layer 33 and the valence band of second semiconductor layer 32.

Referring to FIG. 1, p-type cladding layer 40 is disposed opposite to substrate 10 with quantum well structure 30 between them. P-type cladding layer 40 is disposed on second main surface 30B of quantum well structure 30. P-type cladding layer 40 includes first main surface 40A and a second main surface 40B. At first main surface 40A, p-type cladding layer 40 is in contact with quantum well structure 30. P-type cladding layer 40 is formed of a III-V compound semiconductor. As the III-V compound semiconductor constituting p-type cladding layer 40, for example, AlₓGa₁₋ₓAs (0.10<x<0.90), InₓGa₁₋ₓP (0.40<x<0.60) or the like can be employed. In the present embodiment, for example, p-AlₓGa₁₋ₓAs (x=0.45) having a p-type conductivity type is employed as the compound semiconductors constituting p-type cladding layer 40. For example, C (carbon) can be employed as the p-type impurity contained in p-type cladding layer 40. The thicknesses of P-type cladding layer 40 is, for example, from 300 nm and 3000 nm.

In quantum well structure 30 of semiconductor stack 1 according to the present embodiment, the compositions of first semiconductor layer 31 and third semiconductor layer 33 are changed such that the bandgap decreases toward second semiconductor layer 32. Therefore, it is possible to lengthen the wavelength of light emitted from quantum well structure 30 while suppressing an increase in strain in quantum well structure 30. As described above, semiconductor stack 1 according to the present embodiment is a semiconductor stack capable of lengthening the wavelength of emitted light while suppressing an increase in strain in quantum well structure 30.

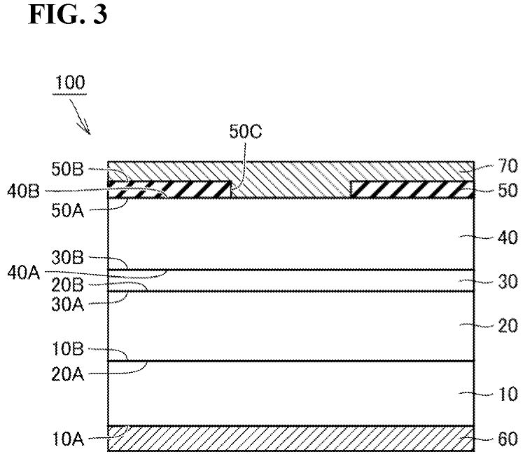

Next, an infrared laser 100 which is an example of a light-emitting device manufactured using semiconductor stack 1 will be described. Referring to FIG. 3, infrared laser 100 according to the present embodiment is manufactured using semiconductor stack 1 according to the present embodiment, and includes substrate 10, n-type cladding layer 20, quantum well structure 30, and p-type cladding layer 40, which are stacked in the same manner as semiconductor stack 1. Infrared laser 100 further includes an insulating layer 50, an n-electrode 60 as a first electrode, and a p-electrode 70 as a second electrode.

N-electrode 60 is disposed in contact with substrate 10 so as to cover first main surface 10A of substrate 10. N-electrode 60 is made of a conductor such as a metal. More specifically, n-electrode 60 can be made of a conductive material, for example, a metal such as Ti (titanium), Pt (platinum) and Au (gold) or an alloy thereof. N-electrode 60 is in ohmic contact with substrate 10.

Insulating layer 50 is disposed in contact with p-type cladding layer 40 so as to cover second main surface 40B of p-type cladding layer 40. Insulating layer 50 is disposed on second main surface 40B of p-type cladding layer 40. Insulating layer 50 includes a first main surface 50A and a second main surface 50B. At first main surface 50A, insulating layer 50 is in contact with p-type cladding layer 40. Insulating layer 50 is made of an insulator such as silicon nitride or silicon oxide. An opening 50C that penetrates insulating layer 50 in the thickness direction is formed in insulating layer 50. In opening 50C, second main surface 40B of p-type cladding layer 40 is exposed.

P-electrode 70 is disposed in contact with insulating layer 50 and p-type cladding layer 40 so as to cover second main surface 50B of insulating layer 50 and fill opening 50C. P-type cladding layer 40 exposed from opening 50C is in contact with p-electrode 70. P-electrode 70 is made of a conductor such as a metal. More specifically, p-electrode 70 can be made of a conductive material, for example, a metal such as Ti (titanium), Pt (platinum) and Au (gold) or an alloy thereof. P-electrode 70 is in ohmic contact with p-type cladding layer 40.

Infrared laser 100 is a Fabry-Perot (FP) type laser element of an edge-emitting laser. Reflection mirrors formed by cleavage of crystals constituting quantum well structure 30 are formed on end surfaces of quantum well structure 30 facing each other. When a voltage is applied between n-electrode 60 and p-electrode 70, electrons are supplied from n-type cladding layer 20 side and holes are supplied from p-type cladding layer 40 side to quantum well structure 30. Thus, light (infrared light) having a wavelength corresponding to the bandgap in quantum well structure 30 is generated. More specifically, due to the transition of electrons between the conduction band of first semiconductor layer 31 and the valence band of second semiconductor layer 32, and between the conduction band of third semiconductor layer 33 and the valence band of second semiconductor layer 32, light having wavelengths corresponding to bandgaps therebetween is generated. In the present embodiment, due to the transition of electrons between the first level (E1 level) of the conduction band of first semiconductor layer 31 and the first level (hh1 level) of the heavy hole (hh) of second semiconductor layer 32, and between the first level of the conduction band of third semiconductor layer 33 and the first level of the heavy hole of second semiconductor layer 32, light having wavelengths corresponding to bandgaps therebetween is generated. The light generated in quantum well structure 30 is confined in quantum well structure 30, resonates by going back and forth between the reflection mirrors, and causes laser oscillation. As a result, laser light is emitted from the end face of quantum well structure 30.

Infrared laser 100 according to the present embodiment includes semiconductor stack 1 according to the present embodiment. Therefore, infrared laser 100 is a semiconductor stack capable of lengthening the wavelength of emitted light while suppressing an increase in strain in quantum well structure 30.

Next, an outline of a method of manufacturing semiconductor stack 1 and infrared laser 100 according to the present embodiment will be described with reference to FIGS. 1 to 5.

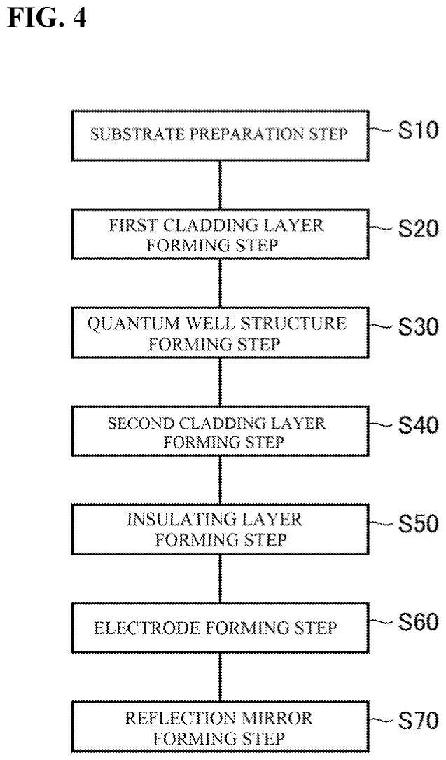

Referring to FIG. 4, in the method of manufacturing semiconductor stack 1 and infrared laser 100 according to the present embodiment, a substrate preparation step is first performed as a step (S10). In this step (S10), referring to FIG. 1, for example, substrate 10 made of 2-inch (50.8 mm) GaAs is prepared. More specifically, substrate 10 made of GaAs is obtained by slicing an ingot made of GaAs. After the surface of substrate 10 is polished, substrate 10 in which the flatness and cleanliness of second main surface 10B are ensured through a process such as cleaning is prepared.

Referring to FIG. 4, next, a first cladding layer forming step is performed as a step (S20). In this step (S20), referring to FIG. 1, n-type cladding layer 20 made of, for example, n-AlₓGa₁₋ₓAs (x=0.45) which is a III-V compound semiconductor is formed by vapor phase growth so as to be in contact with second main surface 10B of substrate 10. In the formation of n-type cladding layer 20, TMA (trimethylaluminum) can be used as a raw material of Al, TEGa (triethylgallium) can be used as a raw material of Ga, TBAs (tertiarybutylarsine) can be used as a raw material of As, and TeESi (tetraethylsilane) can be used as a raw material of Si as an n-type impurity.

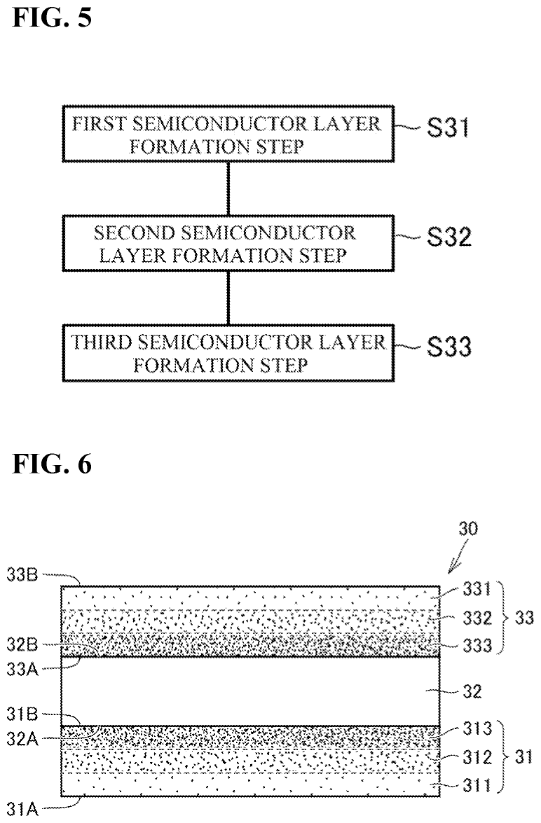

Referring to FIG. 4, next, a quantum well structure forming step is performed as a step (S30). Referring to FIGS. 4 and 5, the quantum well structure formation step includes a first semiconductor layer formation step (S31), a second semiconductor layer formation step (S32), and a third semiconductor layer formation step (S33). First, in step (S31), referring to FIG. 2, first semiconductor layer 31 made of, for example, InₓGa₁₋ₓAs_{y}N_{1-y} (where 0<x<0.5, 0.9<y<1.0) is formed by vapor phase growth so as to be in contact with second main surface 20B of n-type cladding layer 20. As a raw material of In, for example, TMIn (trimethylindium) can be used. As a raw material of Ga, for example, TEGa (triethylgallium) can be used. As a raw material of As, for example, TBAs (tertiarybutylarsine) can be used. As a raw material of N, for example, DMI-ly (dimethylhydrazine) can be used. At this time, by gradually increasing the ratio (for example, the ratio of the flow rate) of TMIn in the entire raw material gases, it is possible to form first semiconductor layer 31 in which the ratio of In increases as it approaches the second semiconductor layer. As a result, it is possible to obtain first semiconductor layer 31 in which the bandgap decreases toward the second semiconductor layer.

Next, referring to FIG. 4, step (S32) is performed. In this step (S32), referring to FIG. 2, second semiconductor layer 32 made of, for example, GaSbₜAs₁₋ₜ or GaBiᵤAs₁₋ᵤ (where 0<t<0.5 and 0<u<0.5) is formed by vapor phase growth so as to be in contact with second main surface 31B of first semiconductor layer 31. As a raw material of Ga, for example, TEGa can be used. As a raw material of Sb, for example, TMSb (trimethylantimony) can be used. As a raw material of As, for example, TBAs can be used. As a raw material of Bi, for example, TMBi (trimethylbismuth) can be used.

Next, referring to FIG. 4, step (S33) is performed. In this step (S33), referring to FIG. 2, third semiconductor layer 33 made of, for example, InₓGa₁₋ₓAs_{y}N_{1-y} (where 0<x<0.5, 0.9<y<1.0) is formed by vapor phase growth so as to be in contact with second main surface 32B of second semiconductor layer 32. The raw materials of the elements constituting third semiconductor layer 33 may be the same as those in the step (S31). At this time, by gradually decreasing the ratio (for example, the ratio of the flow rate) of TMIn in the entire raw material gases, it is possible to form third semiconductor layer 33 in which the ratio of In increases as it approaches the second semiconductor layer. Thereby, it is possible to obtain third semiconductor layer 33 in which the bandgap decreases as it approaches the second semiconductor layer.

Referring to FIG. 4, next, a second cladding layer forming step is performed as a step (S40). In this step (S40), referring to FIG. 1, p-type cladding layer 40 made of, for example, p-AlₓGa₁₋ₓAs (x=0.45) which is a III-V compound semiconductor is formed by vapor phase growth so as to be in contact with second main surface 30B of quantum well structure 30. In the formation of p-type cladding layer 40, TMA can be used as a raw material of Al, TEGa can be used as a raw material of Ga, TBAs can be used as a raw material of As, and CBr₄ (tetrabromomethane) can be used as a raw material of C which is a p-type impurity.

By performing the above steps (S10) to (S40), semiconductor stack 1 of the present embodiment is completed. The production efficiency of semiconductor stack 1 can be improved by performing the steps (S20) to (S40) by metal-organic chemical vapor deposition. The steps (S20) to (S40) are not limited to a metal-organic chemical vapor deposition using only metal-organic raw materials (all-metal-organic chemical vapor deposition). For example, a metal-organic chemical vapor deposition using hydrides such as AsH₃ (arsine) as a raw material of As may be employed. By adopting the all-metal-organic chemical vapor deposition, semiconductor stack 1 made of a high-quality crystal can be obtained. Further, semiconductor stack 1 can be manufactured by a method other than the metal-organic chemical vapor deposition, and for example, MBE (molecular beam epitaxy) method may be used.

Next, referring to FIG. 4, an insulating layer forming step is performed as a step (S50). In this step (S50), referring to FIGS. 1 and 3, insulating layer 50 is formed so as to cover second main surface 40B of p-type cladding layer 40 of semiconductor stack 1 manufactured in the above steps (S10) to (S40). Specifically, insulating layer 50 made of an insulator such as silicon oxide or silicon nitride is formed by CVD (Chemical Vapor Deposition), for example.

Next, an electrode forming step is performed as a step (S60). In this step (S60), referring to FIG. 3, n-electrode 60 and p-electrode 70 are formed. Specifically, a mask having an opening portion at a position corresponding to a desired region where opening 50C is to be formed is formed on insulating layer 50, and opening 50C is formed using the mask. Thereafter, n-electrode 60 and p-electrode 70 made of an appropriate conductor are formed by, for example, vapor deposition.

Next, a reflection mirror forming step is performed as a step (S70). In this step (S70), referring to FIG. 3, a reflection mirror is formed for semiconductor stack 1 in which insulating layer 50, n-electrode 60, and p-electrode 70 are formed. Specifically, reflection mirrors formed by cleavage of crystals constituting quantum well structure 30 are formed on end surfaces (end surfaces on the near side and the far side of the paper surface in FIG. 3) of quantum well structure 30 facing each other. Thereafter, semiconductor stack 1 is separated into individual elements by dicing, for example. Through the above procedure, infrared laser 100 of this embodiment can be manufactured.

### Second Embodiment

A semiconductor stack and a light-emitting device according to a second embodiment, which is another embodiment of the semiconductor stack and the light-emitting device according to the present disclosure, will be described. FIG. 6 is a schematic cross-sectional view showing a quantum well structure of a semiconductor stack according to the second embodiment, and corresponds to FIG. 2 of the first embodiment.

The semiconductor stack and the semiconductor laser according to the second embodiment have basically the same structures as those of the first embodiment, and exhibit the same effects. However, the semiconductor stack and the semiconductor laser according to the second embodiment are different from those according to the first embodiment in the structures of first semiconductor layer 31 and third semiconductor layer 33 of quantum well structure 30.

Referring to FIG. 6, the compositions of first semiconductor layer 31 and third semiconductor layer 33 of quantum well structure 30 according to the second embodiment are changed in stages as they approach second semiconductor layer 32. Specifically, first semiconductor layer 31 and third semiconductor layer 33 in the second embodiment include first component layers 311, 331, second component layers 312, 332, and third component layers 313, 333, respectively. First component layers 311, 331, second component layers 312, 332, and third component layers 313, 333 are stacked in this order from the side farther from second semiconductor layer 32. The concentration of In is lowest in first component layers 311, 331 and highest in third component layers 313, 333. The concentration of In in second component layers 312, 332 is higher than concentration in first component layers 311, 331 and lower than concentration in third component layers 313, 333. The concentration of In is constant inside each of first component layers 311, 331, second component layers 312, 332, and third component layers 313, 333. That is, in first semiconductor layer 31 and third semiconductor layer 33 according to the second embodiment, the concentration of In increases in stages as it approaches second semiconductor layer 32. Semiconductor stack 1 and infrared laser 100 including first semiconductor layer 31 and third semiconductor layer 33 can be easily manufactured by changing the flow rate of the raw material gas of In in stages (in three stages) in the steps (S31) and (S33) of the first embodiment. Even when first semiconductor layer 31 and third semiconductor layer 33 having such a structure are employed, the same effects as those in the first embodiment can be obtained.

### Examples

In order to confirm the effects of the semiconductor stack and the light-emitting device of the present disclosure, a calculation was performed to calculate the strain in quantum well structure 30 and the wavelength of light generated in quantum well structure 30, assuming an infrared laser having the same structure as that the first embodiment. For comparison, the same calculation was performed for an infrared laser in which the concentrations of In in first semiconductor layer 31 and third semiconductor layer 33 were constant.

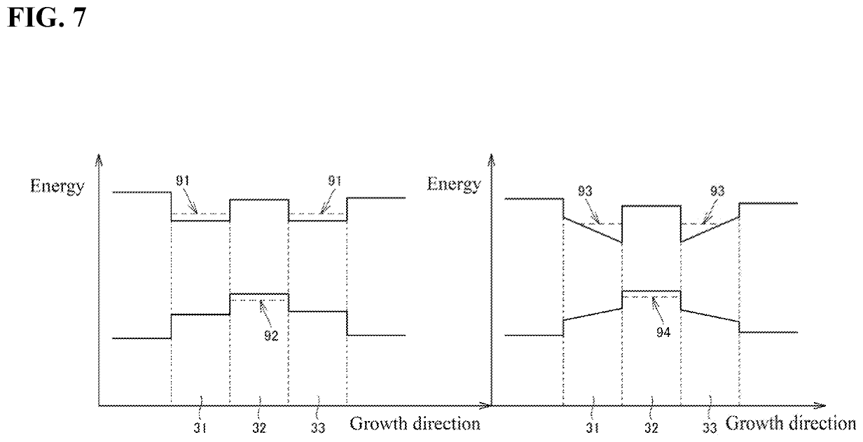

FIG. 7 shows the band structure of quantum well structure 30 of the example and the comparative example. In FIG. 7, the band diagram of quantum well structure 30 of the example is shown on the right side, and the band diagram of quantum well structure 30 of the comparative example is shown on the left side. The horizontal axis corresponds to the distance in the growth direction (thickness direction of quantum well structure 30). The vertical axis corresponds to energy. In FIG. 7, the lower solid line indicates the valence band energy, and the upper solid line indicates the conduction band energy. The thicknesses of first semiconductor layer 31, second semiconductor layer 32, and third semiconductor layer 33 were set to 4 nm, respectively. The concentrations of In in first semiconductor layer 31 and third semiconductor layer 33 of the example were set to 44 at % at the interface with second semiconductor layer 32 and 24 at % at the opposite interface in the thickness direction, and were set to change at a constant rate (change according to a linear function) with respect to distances from the interface with second semiconductor layer 32. On the other hand, the concentration of In in first semiconductor layer 31 and third semiconductor layer 33 of the comparative example was set to a fixed value of 34 at %. In both example and comparative example, the concentration of Sb in second semiconductor layer 32 was set to a fixed value of 20.5 at %.

Referring to FIG. 7, in each of first semiconductor layer 31, second semiconductor layer 32, and third semiconductor layer 33 of the comparative example, the energy of the valence band and the conduction band is constant. On the other hand, in each of first semiconductor layer 31 and third semiconductor layer 33 of the example, the energy of the valence band and the conduction band is inclined, and the bandgap decreases toward second semiconductor layer 32. In first semiconductor layer 31 and third semiconductor layer 33 of the comparative example, an E1 level 91 and an hh1 level 92 indicated by broken lines are formed. On the other hand, in first semiconductor layer 31 and third semiconductor layer 33 of the example, an E1 level 93 and an hh1 level 94 indicated by broken lines are formed. Due to the gradient of the composition in first semiconductor layer 31 and third semiconductor layer 33, E1 level 93 formed in the conduction band of first semiconductor layer 31 and third semiconductor layer 33 of the example has lower energy than E1 level 91 of the comparative example. On the other hand, when the total strain amount in quantum well structure 30 was calculated, it was 25.6% in both the example and the comparative example.

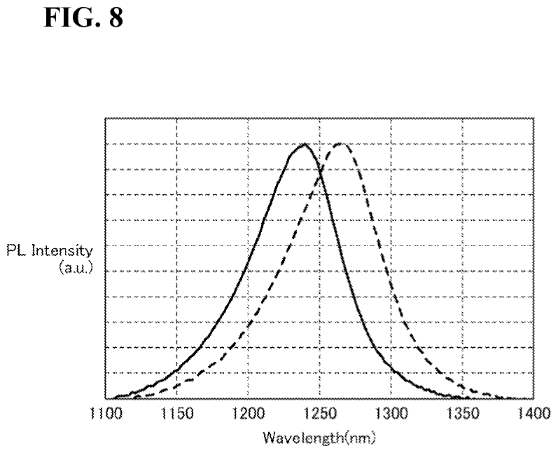

FIG. 8 shows the light emission characteristics of quantum well structures 30 of example and comparative example having the above structure. In FIG. 8, the horizontal axis represents the wavelength of light (unit: nm), and the vertical axis represents the intensity of light (arbitrary unit). In FIG. 8, the comparative example is indicated by a solid line, and the example is indicated by a broken line. As is clear from FIG. 8, it is confirmed that by adopting quantum well structure 30 of the example, a longer wavelength of light is achieved compared to the comparative example. As described above, the total strain amounts in quantum well structures 30 of the example and the comparative example are the same value. From the above calculation results, according to the semiconductor stack and the light-emitting device of the present disclosure, it is confirmed that the wavelength of emitted light can be made longer while suppressing an increase in strain in the quantum well structure. The peak wavelengths of the comparative examples are 1240 nm, whereas the peak wavelengths of the examples are 1256 nm.

In the above-described embodiments and examples, the case where one first semiconductor layer 31, one second semiconductor layer 32, and one third semiconductor layer 33 are included has been described, but the semiconductor stack and the light-emitting device of the present disclosure are not limited thereto. First semiconductor layer 31, second semiconductor layer 32, and third semiconductor layer 33 may be repeatedly stacked in this order a plurality of times. In this case, a spacer layer made of, for example, GaAs may be disposed between first semiconductor layer 31 and third semiconductor layer 33 facing each other. When the number of stacks is large, a strain compensation layer made of, for example, GaAsP may be disposed instead of the spacer layer from the viewpoint of reducing strain.

In the above embodiments, the Fabry-Perot laser element has been described as an example of the light-emitting device, but the light-emitting device of the present disclosure is not limited thereto. The light-emitting device of the present disclosure may be applied to a light-emitting device having any other structure, such as a DFB (distributed feedback laser) laser.

It should be understood that the embodiments and examples disclosed herein are illustrative in all respects and are not restrictive in any respect. The scope of the present invention is defined not by the above description but by the claims, and is intended to include meanings equivalent to the claims and all modifications within the scope.

1. A semiconductor stack comprising:
a first-conductivity-type layer formed of a III-V compound semiconductor;
a quantum well structure formed of III-V compound semiconductors; and
a second-conductivity-type layer formed of a III-V compound semiconductor and having a conductivity type different from a conductivity type of the first-conductivity-type layer,
wherein the first-conductivity-type layer, the quantum well structure, and the second-conductivity-type layer are stacked in this order,
the quantum well structure includes
a first semiconductor layer,
a second semiconductor layer disposed on and in contact with the first semiconductor layer, and
a third semiconductor layer disposed on and in contact with the second semiconductor layer,
in the first semiconductor layer and the third semiconductor layer, compositions of the first semiconductor layer and the third semiconductor layer are changed such that a bandgap decreases toward the second semiconductor layer, and
transition of an electron is possible between a conduction band of each of the first semiconductor layer and the third semiconductor layer and a valence band of the second semiconductor layer.

2. The semiconductor stack according to claim 1, wherein the first semiconductor layer and the third semiconductor layer are formed of the same III-V compound semiconductor.

3. The semiconductor stack according to claim 2, wherein the first semiconductor layer and the third semiconductor layer have the same thickness.

4. The semiconductor stack according to claim 1, further comprising:
a substrate formed of GaAs and stacked on an opposite side of the first-conductivity-type layer from the quantum well structure,
wherein the III-V compound semiconductors constituting the first semiconductor layer and the third semiconductor layer are each InₓGa₁₋ₓAs_{y}N_{1-y}, and
the III-V compound semiconductor constituting the second semiconductor layer is GaSbₜAs₁₋ₜ or GaBiᵤAs₁₋ᵤ,
where 0<x<0.5, 0.9<y<1.0, 0<t<0.5, and 0<u<0.5 are satisfied.

5. The semiconductor stack according to claim 1, wherein the compositions of the first semiconductor layer and the third semiconductor layer are changed at a constant rate toward the second semiconductor layer.

6. The semiconductor stack according to claim 1, wherein the compositions of the first semiconductor layer and the third semiconductor layer are changed in stages toward the second semiconductor layer.

7. The semiconductor stack according to claim 1, wherein the first semiconductor layer, the second semiconductor layer, and the third semiconductor layer each have a thickness of 1 nm to 8 nm.

8. A light-emitting device comprising:
the semiconductor stack according to claim 1; and
an electrode disposed in contact with the semiconductor stack.
